(19) United States
(12) Patent Application Publication
(10) Pub. No.: US 2005/0247672 A1
(43) Pub. Date: Nov. 10, 2005

(54) Plasma etching method

(76) Inventor: Tetsuya Tatsumi, Kanagawa (JP)

Correspondence Address: ROBERT J. DEPKE;LEWIS T. STEADMAN, TREXLER, BUSHNELL, GLANGLORGI, BLACKSTONE & MARR, 105 WEST ADAMS STREET, SUITE 3600, CHICAGO, IL, 60603-6299, US

(21) Appl. No.: 11/110,380

(22) Filed: Apr. 20, 2005

(30) Foreign Application Priority Data
Apr. 23, 2004 (JP) 2004-127526

(51) Int. Cl. C23F 1/00; H01L 21/302

(52) U.S. Cl. 216/67; 438/723; 438/689

(57) ABSTRACT

A method for plasma etching an insulating layer by using a fluorocarbon etching gas, the method including controlling the sheath potential Vₛ (or ion accelerating voltage) that appears on the outermost surface of the plasma surrounding parts of the plasma etching equipment in response to the value (Fc) of F₀/C₀, where C₀ and F₀ each denote the total amount of carbon atoms and fluorine atoms constituting the fluorocarbon etching gas, so as to avoid deposition of residues on the plasma surrounding parts. This method permits stable plasma etching.

### BACKGROUND OF THE INVENTION

The present invention relates to a plasma etching method.

The recent development of ULSI devices aims at fast operation and low power consumption. For this purpose, the latest ULSI devices usually have insulating layers formed from a low dielectric constant material and multi-level interconnections formed from copper. In this connection, there is an increasing demand for continuously performing plasma etching on an object of laminate structure in the same plasma etching equipment. Plasma etching is becoming more complex than before as the result of recent technical advance including adoption of low dielectric constant materials (which are vulnerable to variation in plasma etching), more stringent requirements for fabrication precision accompanied by miniaturization, and diversified objects of laminate structure to be etched.

Complexity of plasma etching will be understood from FIG. 5 which illustrates how the etch rate varies in plasma etching on SiO₂, SiOH, and SiOCH with C₄H₈ as the etching gas. Incidentally, the abscissa and ordinate in FIG. 5 represent C₄H₈ flow rate and etch rate, respectively. It is apparent from FIG. 5 that plasma etching on SiOCH remarkably varies in etch rate depending on the flow rate of etching gas, in contrast to plasma etching on SiO₂. This suggests that latitude for plasma etching is very narrow although it depends on the material of objects for etching. The consequence of narrow latitude is that even the slightest deviation from the predetermined plasma etching condition causes serious troubles such as anomalous line width, anomalous etch suspension, and occurrence of residues.

Plasma stability is realized as the result of stable reaction with those parts which surround plasma in the plasma etching equipment (referred to as “plasma surrounding parts” for brevity hereinafter). Unfortunately, there is an instance where residues deposit on the plasma surrounding parts during plasma etching as schematically indicated by solid lines in FIG. 6. Deposition of residues varies depending on the material of objects for etching. (Note the second and fourth layers of the five-layered object shown in FIG. 6.) There is also an instance where no deposition occurs on the plasma surrounding parts but deposited residues are removed from the plasma surrounding parts. (Note the third and fifth layers of the five-layered object shown in FIG. 6)

Plasma etching on an object of laminate structure usually proceeds as shown in FIG. 6. In other words, deposition on the plasma surrounding parts differs from that in subsequent plasma etching. This causes deviation from the predetermined plasma etching condition (or plasma characteristics). Also, in the case where plasma etching is performed continuously on an object of laminate structure in the same plasma etching equipment, there is an instance where deposition on the plasma surrounding parts occurs differently from one plasma etching step to another as shown by the solid and dotted lines in FIG. 6. Thus, deposition on the plasma surrounding parts that occurs during plasma etching on one layer affects plasma etching on another layer. This causes fluctuations in plasma etching conditions.

There has been disclosed in Japanese Patent Laid-open No. Hei 8-288267 (hereinafter described as a Patent Document 1) a parallel flat plate type plasma etching equipment which is provided with a means to remove deposits from the upper electrode. The disclosure claims that the upper electrode is made free of polymer deposition and protected from etching if it is supplied with adequate RF electric power. (See paragraph No. 0022 of the specification.) It also claims that the upper electrode with a clean, deposit-free surface generates and sustains a stable, reproducible plasma in the etching chamber. (See paragraph No. 0026 of the Patent Document 1.)

### SUMMARY OF THE INVENTION

The above-mentioned patent document 1, however, mentions nothing about the relation between the composition of etching gas and the RF electric power to be applied to the upper electrode. In other words, it mentions nothing about how to control potential at the plasma surrounding parts when the object for etching is replaced and the etching gas is replaced accordingly, if plasma etching is to be performed without deposition and etching on the plasma surround parts.

It is desirable to provide a method for plasma etching an insulating layer by using a plasma etching equipment and a fluorocarbon etching gas, the method being able to perform stable plasma etching without causing deposition on the plasma surround parts.

The above-mentioned desire is achieved by the first embodiment of the present invention which is concerned with a method for plasma etching an insulating layer by using a plasma etching equipment and a fluorocarbon etching gas, the method including controlling the sheath potential (Vₛ) that appears on the outermost surface of the plasma surrounding parts of the plasma etching equipment in response to the value of F₀/C₀, where C₀ and F₀ each denote the total amount of carbon atoms and fluorine atoms constituting the fluorocarbon etching gas, so as to avoid deposition on the plasma surrounding parts.

The plasma etching method according to the first embodiment of the present invention may be modified such that the etching gas contains oxygen gas to meet the condition that C₀>O₀, where O₀ denotes the total amount of oxygen atoms in the etching gas. Incidentally, it is assumed that the dissociation degree of oxygen gas in plasma is equal to that of fluorocarbon gas in plasma. Moreover, the first embodiment of the present invention may also be modified such that the etching gas contains nitrogen gas to meet the condition that C₀>α·N₀, where N₀ denotes the total amount of nitrogen atoms in the etching gas and α denotes the dissociation degree of nitrogen gas in plasma. Incidentally, C₀>α·N₀ may be replaced by C₀>20·N₀ because the value of α is usually about 20. The etching gas may further contain argon gas.

The above-mentioned desire is achieved by the second embodiment of the present invention which is concerned with a method for plasma etching each layer of an object of M-layered structure (M≧2) having at least one insulating layer by using a plasma etching equipment and a fluorocarbon etching gas, the method including controlling the sheath potential Vₘ₋ₛ that appears on the outermost surface of the plasma surrounding parts of the plasma etching equipment when the mth layer (m=1, 2, . . . M) undergoes plasma etching, in response to the value of Fₘ₋₀/Cₘ₋₀, where Cₘ₋₀ and Fₘ₋₀ each denote the total amount of carbon atoms and fluorine atoms constituting the fluorocarbon etching gas used for plasma etching of the mth layer, so as to avoid deposition on the plasma surrounding parts.

The plasma etching method according to the second embodiment of the present invention may be modified such that the etching gas used for etching at least the insulating layer contains oxygen gas to meet the condition that C₀>O₀, where O₀ denotes the total amount of oxygen atoms in the etching gas. Incidentally, it is assumed that the dissociation degree of oxygen gas in plasma is equal to that of fluorocarbon gas in plasma. Moreover, the second embodiment of the present invention may also be modified such that the etching gas used for etching at least the insulating layer contains nitrogen gas to meet the condition that C₀>α·N₀, where N₀ denotes the total amount of nitrogen atoms in the etching gas and α denotes the dissociation degree of nitrogen gas in plasma. Incidentally, C₀>α·N₀ may be replaced by C₀>20·N₀ because the value of α is usually about 20. The etching gas may further contain argon gas.

The plasma etching method according to the first and second embodiments of the present invention controls the sheath potential Vₛ or Vₘ₋ₛ which occurs on the outermost surface of the plasma surrounding parts during plasma etching. The sheath potential is the ion accelerating voltage and it is also an electric field applied onto the sheath that appears in contact with the surface of the plasma surrounding parts. The sheath is a thin layer of ions spontaneously accumulating on the surface of the plasma surrounding parts, and it prevents the inflow of excess electrons. The magnitude of the electric field equals the difference between the potential of plasma and the potential of the plasma surrounding parts.

In addition, the plasma etching method according to the first and second embodiments of the present invention controls the sheath potential Vₛ or Vₘ₋ₛ so as to avoid deposition of residues on the plasma surrounding parts. “Avoid deposition of residues” means keeping substantially invariable the thickness of deposition on the plasma surrounding parts during plasma etching. In fact, deposition on the plasma surrounding parts remains in a stationary state while plasma etching is proceeding on the insulating layer or the mth layer. In a stationary state, the thickness of deposition on the plasma surrounding parts is usually about 2 to 5 nm.

The plasma etching method according to the first and second embodiments, including their modifications, of the present invention should preferably be executed in such a way as to keep the sheath potential Vₛ or Vₘ₋ₛ on the outermost surface of the plasma surrounding parts above the potential at which no deposition of residues occurs on the plasma surrounding parts but below the potential at which etching takes place on the material constituting the plasma surrounding parts. “No deposition of residues occurs” means that the thickness of deposition in the stationary state remains substantially constant during plasma etching.

The plasma etching method according to the present invention is applied to the insulating layer which should preferably be composed of a silicon-containing material having a relative permittivity k (=ε/ε₀) no lower than 3.5. Examples of such a material include SiOCH, SiOH, SiOF, bubble-containing silicon oxide xerogel, nanoporous silica, SiO₂, SiN, SiON, SiC, and SiCN.

The plasma etching method according to the second embodiment of the present invention is applied to an object of M-layered structure (M≧2) having at least one insulating layer. The M-layered structure may be composed entirely of insulating layers, or it may be composed of insulating layers and masking layers in combination, or insulating layers and resist layers in combination, or insulating layers, masking layers, and resist layers in combination. The masking layers may be formed from SiO₂, SiN, SiC, or SiOCH individually or in combination. The resist layers may be in laminate structure formed from organic polymers.

The plasma etching method according to the present invention may be implemented by using any plasma etching equipment which includes those of parallel flat plate type, magnetic field microwave type, helicon wave type, induced combination type, and UHF/VHF type.

The term “plasma surrounding parts” used in the plasma etching method according to the present invention embraces the upper electrode, side walls, lower electrode (excluding the area covered by a semiconductor substrate or wafer), side of lower electrode, focusing ring (to surround the electrodes), and confinement ring (to prevent diffusion of plasma), in the case of parallel flat plate type plasma etching equipment. It also embraces the RF supply window made of a dielectric material in the case of magnetic field microwave type or induced combination type. The plasma surrounding parts may be formed from any of silicon (Si), alumina (Al₂O₃), quartz, and yttria (Y₂O₃).

Silicon, alumina, quartz, or yttria constituting the plasma surrounding parts undergoes etching at a potential shown in Table 1 below.

TABLE 1

| | Potential | Potential for |
|---|---|---|
| | for etching | substantial |
| Material | (V) | etching (V) |
| Silicon | 50 | 450 |
| Alumina | 100 | 500 |
| Quartz | 100 | 500 |
| Yttria | 150 | 550 |

As mentioned earlier, when plasma etching is performed on the insulating layer or the mth layer, there occurs deposition of residues on the plasma surrounding parts. The thickness of deposition in a stationary state is about 2 to 5 nm. The deposition in a stationary state decreases ion energy (about 200 V per nm of deposition). Therefore, assuming 2 nm for the thickness of deposition, the potential at which the plasma surrounding parts undergo substantial etching is “potential for etching” plus 400 V. The increased value is indicated as “potential for substantial etching” in Table 1.

The plasma etching method according to the present invention employs a fluorocarbon gas, which is exemplified by CF₄, CH₂F₂, C₄F₈, C₅F₈, C₄F₆, C₂F₄, C₃F₆, CHF₃, and CH₃F. They may be used alone or in combination with one another depending on the material from which the layer for plasma etching is formed.

In the case where only one kind of fluorocarbon gas is used, the value of F₀/C₀ or Fₘ₋₀/Cₘ₋₀ is equal to the number of fluorine atoms divided by the number of carbon atoms in the formula representing the fluorocarbon gas. On the other hand, in the case where more than one kind of fluorocarbon gas is used, the value of F₀/C₀ or Fₘ₋₀/Cₘ₋₀ is defined by the equation (1) below.
F₀/C₀ or Fₘ₋₀/Cₘ₋₀=(Σ FLⱼ·Fⱼ)/(Σ FLⱼ·Cⱼ) (1)
where, FLⱼ denotes the flow rate of each component of the fluorocarbon gas (j=1, 2, . . . J, Σ FLⱼ=1); Cⱼ denotes the number of carbon atoms in the formula representing each component of the fluorocarbon gas; and Fⱼ denotes the number of fluorine atoms in the formula representing each component of the fluorocarbon gas. The symbol Σ in the equation (1) means the sum of j=1 to j=J. The equation (1) is based on the assumption that all the components (as many as J) of the fluorocarbon gas have approximately the same degree of dissociation in plasma, although the degree of dissociation should be taken into account for strict discussion.

The plasma etching method according to the present invention includes the step of controlling the sheath potential Vₛ or Vₘ₋ₛ that appears on the outermost surface of the plasma surrounding parts, in response to the value of F₀/C₀ or Fₘ₋₀/Cₘ₋₀ of the fluorocarbon gas. This control should preferably be performed in such a way as to satisfy the equation (2) below.
−155 Fc+600≦Vₛ≦−155 Fc+700 (2)
where, Fc denotes the value of F₀/C₀ or Fₘ₋₀/Cₘ₋₀ and Vₛ (including Vₘ₋ₛ) denotes the sheath potential that appears on the outermost surface of the plasma surrounding parts.

The plasma etching method according to the present invention is accompanied by deposition of residues on the plasma surrounding parts. This deposition is composed of CFₓ and CFₓH_{y} which have released themselves from the plasma. The deposition may also be composed of CO, CN, CFₓ, and HCN which release themselves or are removed form the plasma surrounding parts.

The plasma etching method according to an embodiment of the present invention should preferably be implemented by using a plasma etching equipment provided with a means to measure or calculate the sheath potential Vₛ or Vₘ₋ₛ that appears on the uppermost surface of the plasma surrounding parts. Moreover, the plasma etching equipment should preferably be constructed such that the sheath potential can be performed on more than half the surface area of the plasma surrounding parts. Any of the following methods may be employed to measure or calculate the sheath potential Vₛ that appears on the outermost surface of the plasma surrounding parts.
A method involving measurements of plasma potential with a high-voltage probe.
A method involving measurements of energy distribution of ions with a mass spectrometer (using the ground potential as the reference).
A method by estimation from the relationship which is previously obtained from the sheath potential (measured by the above-mentioned method) and the result of controlling the plasma potential (by application of RF bias voltage or by application of voltage to control the plasma potential).

The plasma etching method according to an embodiment of the present invention includes a step of controlling the sheath potential Vₛ or Vₘ₋ₛ that appears on the outermost surface of the plasma surrounding parts, in response the value of F₀/C₀ or Fₘ₋₀/Cₘ₋₀ of the fluorocarbon gas. In this way it is possible to certainly prevent deposition of residues on the plasma surrounding parts. The absence of deposition on the plasma surrounding parts permits stable plasma etching even when the object for etching and the etching gas are changed. It also permits stable plasma etching on insulating layers formed from a low dielectric constant material which is vulnerable to plasma fluctuation. Another advantage is that the plasma surrounding parts remain unchanged at the start of and during plasma etching on an object of laminate structure. This leads to stable continuous plasma etching. Thus the plasma etching method of the present invention meets requirements for accurate fabrication necessary for miniaturization and is applicable to any object of complex laminate structure without causing serious troubles such as line width fluctuation, anomalous etching suspension, and residue occurrence.

As mentioned above, the present invention permits accurate plasma etching on fine laminate layers sensible to fluctuation. In addition, it permits continuous plasma etching in a single plasma etching equipment. This permits the production facility to run with a less number of equipments in high yields, which leads to cost saving in plasma etching process.

### BRIEF DESCRIPTION OF THE DRAWINGS

FIG. 1 is a schematic diagram showing the parallel flat plate type plasma etching equipment which is suitable for the plasma etching method according to an embodiment of the present invention;

FIG. 2 is a graph showing the relationship between the ion energy and the etch rate of SiO₂, which is observed when an insulating layer of SiO₂ undergoes plasma etching with a variety of etchants;

FIG. 3 is a graph showing the relation between the vale of F₀/C₀ (Fc) which is obtained from the graph in FIG. 2 and the sheath potential Vₛ which appears on the outermost surface of the plasma surrounding parts of the plasma etching equipment;

FIG. 4 is a graph showing the thickness of deposition of residues on the plasma surrounding parts of the plasma etching equipment and the change with time in etch rate, both observed in plasma etching on an insulating layer of SiO₂ in Example 1 and Comparative Example;

FIG. 5 is a graph showing the etch rate in the plasma etching with C₄F₈ as the etching gas which is performed on SiO₂, SiOH, and SiOCH; and

FIG. 6 is a schematic diagram showing deposition of residues on the plasma surrounding parts of the plasma etching equipment, which occurs during plasma etching on an object of five-layered structure.

### DETAILED DESCRIPTION OF THE PREFERRED EMBODIMENTS

The invention will be described in more detail with reference to the accompanying drawings.

### EXAMPLE 1

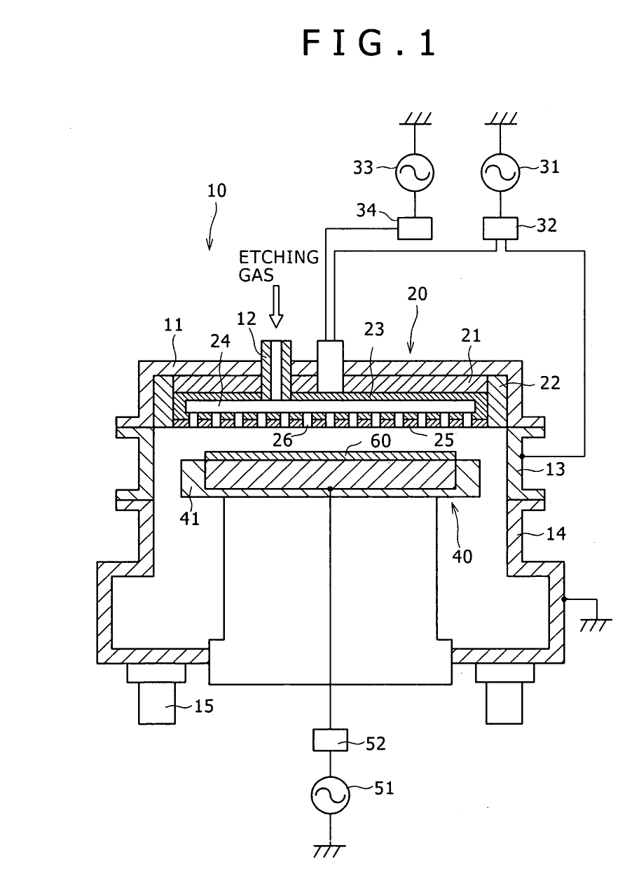

This example demonstrates the plasma etching method according to a first embodiment of the present invention. Plasma etching in this example employs the parallel flat plate type plasma etching equipment as shown in FIG. 1 which is referred to as etching equipment 10 hereinafter. The etching equipment 10 has the upper electrode 20 arranged in its upper part and also has the lower electrode 40 arranged in its lower part. The upper and lower electrodes 20 and 40 are parallel and opposed to each other. The upper and lower electrodes 20 and 40 are supplied with high frequency power, so that an electric field is induced between them. This electric field generates a plasma which dissociates or ionizes the etching gas introduced into the etching equipment 10. The resulting particles move to the surface of the substrate, at which they bring about reaction for plasma etching on the insulating layer etc.

The upper electrode 20 includes the circular-plate-like conducting member 21, the annular dielectric member 22, and the dielectric ring member 23, which are supported by the upper member 11. The inside of the dielectric ring member 23 (the surface of that side in contact with plasma) is covered with the silicon plate 25. The etching gas is supplied into the inside 24 of the dielectric ring member 23 from the gas supply duct 12. The flow rate and mixing ratio of the etching gas are previously determined. The etching gas is finally introduced into the inside of the etching equipment 10 through the through-hole 26 provided in the dielectric ring member 23 and the plate 25.

The dielectric ring member 23 is connected to the power source 31 through the transformer 32. This power source 31 supplies bias electric power (say, 400 kHz) to control the energy of ions impinging on the upper electrode 20. This energy equals the sheath potential Vₛ or Vₘ₋ₛ that appears on the outermost surface of the plasma surrounding parts of the etching equipment. In addition, the dielectric ring member 23 is connected also to the power source 33 for plasma generation through the matching circuit and filter 34.

The lower electrode 40 is connected to the bias power source 52 through the matching circuit and filter 51. The power source 52 supplies bias electric power (say, 13.56 MHz) to control the energy of ions impinging on the layer as an object of plasma etching. This energy will be referred to as energy of ions impinging on the substrate. Incidentally, the lower electrode 40 is provided with an electrostatic chuck, which is not shown in the drawing. The lower electrode 40 is also provided with a means to control the temperature of the object 60 for etching. The temperature controlling means is not shown in the drawing. The lower electrode 40 is surrounded by the lower electrode ring 41, which is made of silicon or quartz and isolated from the lower electrode 40 by an insulating material, such as alumina, which is not shown in the drawing.

The side wall 13 of the etching equipment 10 is made of a non-magnetic metallic material such as aluminum, which is free of heavy metal and has good thermal conductivity. The surface of the side wall 13 is surface treated, such as anodizing, to impart plasma resistance and is coated with alumina.

The side wall 13 of the etching equipment 10 is also connected to the power source 31 through the transformer 32. This power source 31 controls the impinging ion energy. Incidentally, if desirable, the lower electrode ring 41 may also be connected to the power source 31 for impinging ion energy control through the transformer.

The inside of the etching equipment is connected to a vacuum pump (not shown) through the evacuating duct 15. The lower member 14 of the plasma etching equipment 10 is grounded.

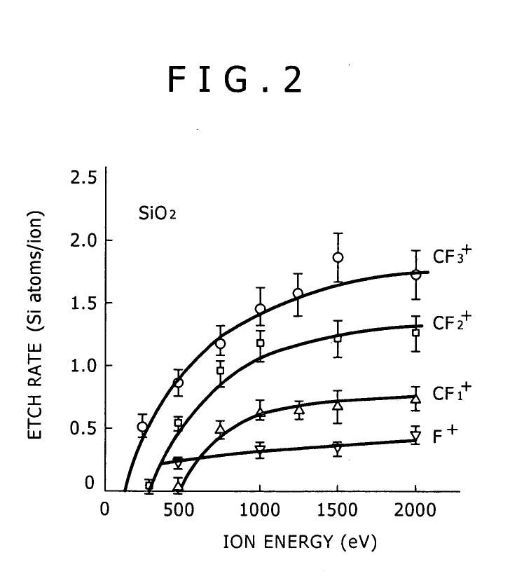

The plasma etching equipment 10 mentioned above was used to perform plasma etching on a silicon semiconductor substrate having an insulating layer of SiO₂ formed thereon. The etchant for plasma etching was F⁺, CF⁺, CF₂⁺, and CF₃⁺. FIG. 2 shows the ion energy (in eV) and the etch rate of SiO₂ (which is expressed in terms of the number of silicon atoms etched by impingement of one ion). Each etchant should be supplied with ion energy so that the etch rate of SiO₂ is zero or nearly zero. In other words, the sheath potential Vₛ or Vₘ₋ₛ or the ion accelerating voltage that appears on the plasma surrounding parts of the etching equipment should be controlled so that the etch rate of SiO₂ is zero or nearly zero. In this way it is possible to prevent deposition of residues from occurring on the plasma surrounding parts and to protect the material of the plasma surrounding parts from etching or sputtering. In the case of plasma etching with fluorocarbon gas which has a small value of F₀/C₀ and is liable to deposition, it is necessary to apply a comparatively high ion energy or to keep high the sheath potential that appears on the plasma surrounding parts. In this way it is possible to prevent deposition of residues on the plasma surrounding parts. The ion energy that keeps the etch rate of SiO₂ at zero or nearly zero varies depending on the value of F₀/C₀ which corresponds to the ratio of F to C brought into the object for etching from the plasma per unit time and per unit area. The larger the value of F₀/C₀, the more it is easy to prevent deposition of residues on the plasma surrounding parts with a lower ion energy (or with a lower sheath potential that appears on the outermost surface of the plasma surrounding parts).

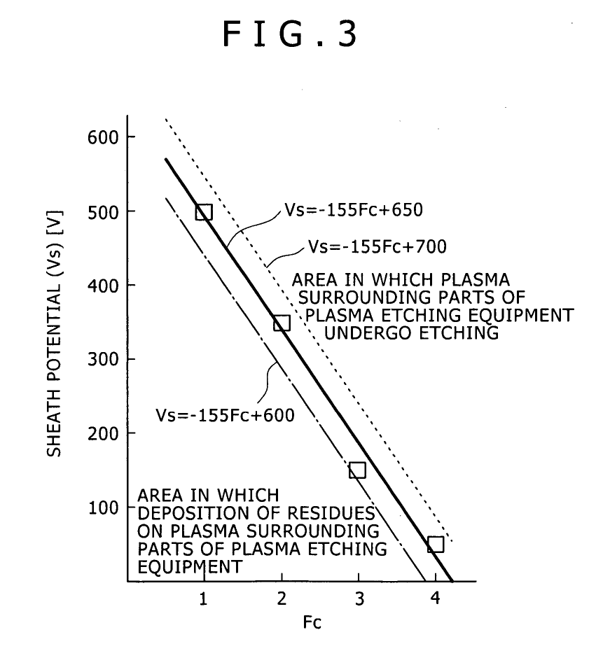

The results shown in FIG. 2 were used to derive the equation (3) below.
Vₛ=−155Fc+650 (3)
where, Fc denotes the value of F₀/C₀ and Vₛ (including Vₘ₋ₛ) denotes the sheath potential that appears on the outermost surface of the plasma surrounding parts. Incidentally, the results shown in FIG. 2 indicate that (Fc, Vₛ)=(1, 500), (2, 350), (3, 150), and (4, 50). FIG. 3 shows the graph of the equation (3) and the confidence limit assuming a confidence coefficient of 0.95. In FIG. 3, the area above the graph of the equation (3) is one in which the plasma surrounding parts substantially undergo etching (sputtering) and the area under the graph of the equation (3) is one in which deposition of residues occurs on the plasma surrounding parts. In this area, the thickness of deposition of residues in stationary state increases as plasma etching proceeds.

As mentioned above, the minimum energy (or the sheath potential that appears on the outermost surface of the plasma surrounding parts) which is necessary to prevent deposition of residues on the plasma surrounding parts varies depending on the value of F₀/C₀ of the fluorocarbon gas. If ions are given an ion energy higher than that which keeps the etch rate of SiO₂ at zero or nearly zero, then deposition of residues does not occur on the plasma surrounding parts and plasma remains stable. However, an excessively high ion energy causes substantial etching (sputtering) to the plasma surrounding parts, gives rise to particles, and consumes the plasma surrounding parts, thereby reducing yields and aggravating production cost. Therefore, it is very important to select an optimal ion energy or the sheath potential that appears on the outermost surface of the plasma surrounding parts. In other words, it is desirable to establish an optimal sheath potential according to the value of Fc. An adequate sheath potential should be the value of Vₛ or Vₘ₋ₛ determined by the equation (3) plus and minus 50 volts, so that deposition of residues on the plasma surrounding parts is minimized and consumption of the plasma surrounding parts is minimized.

Based on the knowledge acquired as mentioned above, plasma etching was performed on an insulating layer of SiO₂ in the following manner.

The plasma etching equipment 10 shown in FIG. 1 is charged with a silicon semiconductor substrate having an insulating layer of SiO₂ formed thereon. The insulating layer has a patterned resist layer formed thereon by lithography. An SiN layer is interposed between the silicon semiconductor substrate and the insulating layer of SiO₂.

Plasma etching on the insulating layer of SiO₂ is performed with a fluorocarbon gas as the etching gas, so that no deposition of residues occurs on the plasma surrounding parts. This plasma etching is intended to form openings for contact holes. This plasma etching is performed in such a way that the sheath potential Vₛ that appears on the outermost surface of the plasma surrounding parts is controlled in response to the value (Fc) of F₀/C₀, where C₀ and F₀ respectively denote the number of carbon atoms and fluorine atoms in the fluorocarbon gas.

To be concrete, the fluorocarbon gas is C₅F₈ and the etching gas has the composition as shown in Table 2. The energy of ions impinging upon the upper electrode 20 (or the sheath potential Vₛ that appears on the outermost surface of the plasma surrounding parts) is controlled at the value shown in Table 2 by controlling the power source 31 for the impinging ion energy. In addition, the energy of ions impinging upon the layer for plasma etching (or the SiO₂ layer in this example) is controlled at the value shown in Table 2 by means of the bias power source 52. The plasma density inside the etching equipment was measured. The results are shown in Table 2.

TABLE 2

| | |
|---|---|
| Etching gas | C₅F₈/Ar/O₂ = 10/600/10 sccm |
| F₀/C₀ (Fc) | 1.6 |
| Pressure | 2.7 Torr |
| Plasma density | 2 × 10¹¹ cm⁻³ |
| Sheath potential (V_{S}) | 400 V |
| Impinging ion energy | 1500 V |

The value (Fc) of F₀/C₀ is 1.6. The etching gas contains oxygen in such an amount as to meet the condition that C₀>O₀, where O₀ denotes the number of oxygen atoms in the etching gas. Moreover, the sheath potential Vₛ that appears on the outermost surface of the plasma surrounding parts is kept at 400 V, which is higher than the potential (about 390 V) at which no deposition of residues occurs on the plasma surrounding parts. Also, the sheath potential Vₛ is kept lower than the potential (450 V and 500 V, respectively) at which silicon and alumina constituting the plasma surrounding parts undergo substantial etching.

After plasma etching on the insulating layer of SiO₂ is completed, next plasma etching is performed on the SiN layer formed under the insulating layer. The condition of plasma etching is shown in Table 3 below.

TABLE 3

| | |
|---|---|
| Etching gas | CF₄/CH₂F₂/Ar/O₂ = 5/5/600/20 sccm |
| Pressure | 2.7 Torr |
| Plasma density | 1 × 10¹¹ cm⁻³ |
| Sheath potential (V_{S}) | 100 V |
| Impinging ion energy | 500 V |

In Example 1, plasma etching on the SiN layer is performed with the etching gas that contains oxygen in such an amount as not to meet the condition that C₀>O₀, where O₀ denotes the number of oxygen atoms in the etching gas. Carbon atoms impinging upon the plasma surrounding parts are mostly removed by reaction with oxygen atoms, regardless of the ion energy (or the sheath potential Vₛ that appears on the outermost surface of the plasma surrounding parts). Therefore, no deposition of residues occurs on the plasma surrounding parts. For this reason, the value of sheath potential Vₛ is kept low as shown in Table 3 from the standpoint of protecting silicon and alumina (constituting the plasma surrounding parts) from substantial etching.

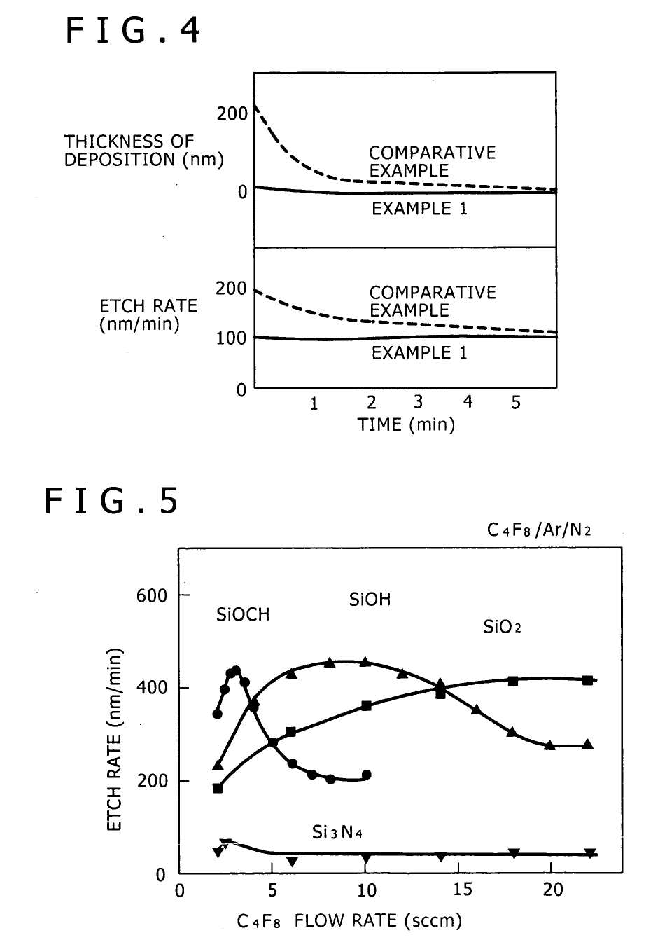

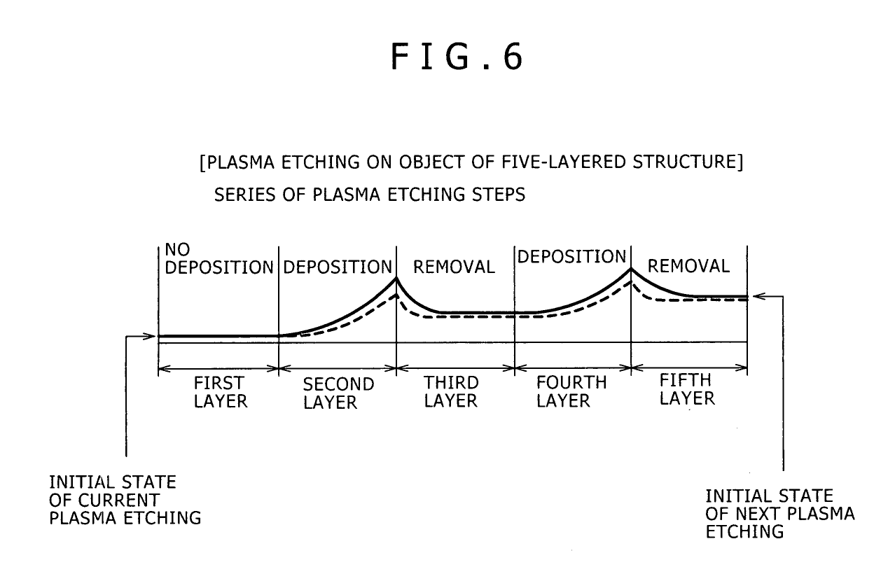

During plasma etching on the insulating layer of SiO₂ under the condition shown in Table 2, the thickness of deposition of residues on the plasma surrounding parts was measured for a prescribed period of time after the start of plasma etching. The change with time in the etch rate was also measured. The results are shown in FIG. 4 (solid lines). For the purpose of comparison, plasma etching was performed in the same way as in Example 1 except that the sheath potential Vₛ was kept at 0 V, and the thickness of deposition of residues on the plasma surrounding parts was measured for a prescribed period of time after the start of plasma etching. The change with time in the etch rate was also measured. The results are shown in FIG. 4 (dotted lines).

It is noted from FIG. 4 that plasma etching on the insulating layer, which is performed according to Example 1, causes no deposition of residues on the plasma surrounding parts and proceeds at a stable etch rate. In other words, deposition of residues on the plasma surrounding parts decreases the etch rate in proportion to the etching time, and the degree of decrease varies depending on the state of deposition of residues.

As mentioned above, plasma etching in Example 1 is performed under the specific condition so that both deposition of residues and etching on the plasma surrounding parts is suppressed during plasma etching. Plasma etching in this manner minimizes the change with time in plasma and realizes a stable process.

### EXAMPLE 2

This example demonstrates the plasma etching method according to a second embodiment of the present invention. Plasma etching in this example was performed by using the etching equipment 10 schematically shown in FIG. 1.

In Example 2, plasma etching was performed on two insulating layers, with the upper layer (the first layer) formed from SiO₂ and the lower layer (the second layer) formed from SiOCH. The two insulating layers are regarded as the M-layered object for plasma etching (M=2 in this case). The etching gas is a fluorocarbon gas.

When plasma etching is performed on the mth layer, the sheath potential Vₘ₋ₛ, which appears on the outermost surface of the plasma surrounding parts, is controlled in response to the value of Fₘ₋₀/Cₘ₋₀, where Cₘ₋₀ and Fₘ₋₀ denote respectively the number of carbon atoms and the number of fluorine atoms in the fluorocarbon gas used for plasma etching on the mth layer (m=1, 2, . . . M), so that no deposition of residues occurs on the plasma surrounding parts.

To be concrete, plasma etching was performed on the upper (first) insulating layer of SiO₂ and the lower (second) insulating layer of SiOCH, under the conditions shown in Table 4 below. Plasma etching on the upper (first) and lower (second) insulating layers was performed with the same fluorocarbon gas under the same conditions. In other words, both the sheath potential V₁₋ₛ and the sheath potential V₂₋ₛ were kept at the same value because the values of F₁₋₀/C₁₋₀ and F₂₋₀/C₂₋₀ are the same.

Plasma etching on the upper and lower insulating layers is intended to make openings for via holes in the upper and lower insulating layers. Incidentally, there is an SiN layer as the etch stopping layer formed between the silicon semiconductor substrate and the lower insulating layer of SiOCH. In Example 2, plasma etching is not performed on the SiN layer. There is a patterned resist layer formed on the upper insulating layer of SiO₂.

TABLE 4

| | |
|---|---|
| Etching gas | C₄F₈/Ar/O₂ = 4/600/6 sccm |
| F₀/C₀ (Fc) | 2.0 |
| Pressure | 2.7 Torr |
| Plasma density | 2 × 10¹¹ cm⁻³ |
| Sheath potential (V_{S}) | 350 V |
| Impinging ion energy | 1500 V |

The value (Fc) of F₀/C₀ is 2.0. The etching gas contains oxygen in such an amount as to meet the condition that C₀>O₀, where O₀ denotes the number of oxygen atoms in the etching gas. Moreover, the sheath potential Vₛ that appears on the outermost surface of the plasma surrounding parts is kept at 350 V, which is higher than the potential (about 340 V) at which no deposition of residues occurs on the plasma surrounding parts. Also, the sheath potential Vₛ is kept lower than the potential at which silicon and alumina constituting the plasma surrounding parts undergo substantial etching.

After plasma etching on the upper insulating layer of SiO₂ and the lower insulating layer of SiOCH is completed, next plasma etching is performed on the resist layer formed on the upper insulating layer. The condition of plasma etching is shown in Table 5 below.

TABLE 5

| | |
|---|---|
| Etching gas | O₂ = 1000 sccm |
| Pressure | 2.7 Torr |
| Plasma density | 1 × 10¹⁰ cm⁻³ |
| Sheath potential (V_{S}) | 30 V |
| Impinging ion energy | 200 V |

Plasma etching on the resist layer does not cause deposition of residues on the plasma surrounding parts. For this reason, the value of sheath potential Vₛ is kept low as shown in Table 5 from the standpoint of protecting silicon and alumina constituting the plasma surrounding parts from substantial etching.

In the course of plasma etching which was performed repeatedly on the object of dual-layer structure under the condition shown in Table 4 and on the resist layer under the condition shown in Table 5, no deposition of residues occurred on the plasma surrounding parts and the etch rate did not change with time. Plasma etching under the condition shown in Table 4, with the sheath potential Vₘ₋ₛ at 0 volt, caused deposition of residues on the plasma surrounding parts, and plasma etching on the resist layer under the condition shown in Table 5 caused the deposited residues to release themselves. To be concrete, in the course of plasma etching on the resist layer, release of the deposited residues lowered the etching selectivity. This manifested itself as the resist layer becoming unsharp at its upper part and fluctuation in pattern transfer difference.

### EXAMPLE 3

This example is a modification of Example 2. In Example 3, plasma etching was performed on an object of three-layered structure to make openings for via holes. The upper layer (the first layer) is a masking layer formed from SiO₂. The intermediate layer (the second layer) is an insulating layer formed from SiOCH. The lower layer (the third layer) is an etch stop layer formed from SiCN. The three-layered object for plasma etching substantially has M=2. There is a patterned resist layer on the mask layer formed from SiO₂.

To be concrete, plasma etching was performed on the mask layer (the first layer) of SiO₂ and the insulating layer (the second layer) of SiOCH under the conditions shown in Table 6 below. Plasma etching on the first and second layers was performed with the same fluorocarbon gas under the same conditions. In other words, both the sheath potential V₁₋ₛ and the sheath potential V₂₋ₛ were kept at the same value because the values of F₁₋₀/C₁₋₀ and F₂₋₀/C₂₋₀ are the same.

TABLE 6

| | |
|---|---|
| Etching gas | C₅F₈/Ar/O₂ = 3/600/6 sccm |
| F₀/C₀ (Fc) | 1.6 |
| Pressure | 2.7 Torr |
| Plasma density | 2 × 10¹¹ cm⁻³ |
| Sheath potential (Vₘ₋ₛ) | 400 V |
| Impinging ion energy | 1500 V |

The value (Fc) of F₀/C₀ is 1.6. The etching gas contains oxygen in such an amount as to meet the condition that C₀>O₀, where O₀ denotes the number of oxygen atoms in the etching gas. Moreover, the sheath potential Vₛ that appears on the outermost surface of the plasma surrounding parts is kept at 400 V, which is higher than the potential (about 390 V) at which no deposition of residues occurs on the plasma surrounding parts. Also, the sheath potential Vₛ is kept lower than the potential at which silicon and alumina constituting the plasma surrounding parts undergo substantial etching.

After plasma etching on the mask layer of SiO₂ and the insulating layer of SiOCH is completed, next plasma etching is performed on the etch stop layer of SiCN formed thereunder. The condition of plasma etching is shown in Table 7 below.

TABLE 7

| | |
|---|---|
| Etching gas | CF₄/CH₂F₂/Ar/O₂ = 10/5/1000/20 sccm |
| Pressure | 2.7 Torr |
| Plasma density | 1 × 10¹⁰ cm⁻³ |
| Sheath potential (V_{S}) | 30 V |
| Impinging ion energy | 200 V |

Plasma etching on the etch stop layer of SiCN does not cause deposition of residues on the plasma surrounding parts, even though the etching gas contains oxygen gas but does not meet the condition that C₀>O₀, where O₀ denotes the number of oxygen atoms in the etching gas. The reason for this is that carbon atoms impinging upon the plasma surrounding parts are mostly removed by reaction with oxygen atoms regardless of the ion energy (or the value of Vₛ that appears on the outermost surface of the plasma surrounding parts). Consequently, the value of sheath potential Vₛ is kept low as shown in Table 7 from the standpoint of protecting silicon and alumina constituting the plasma surrounding parts from substantial etching.

In the course of plasma etching which was performed repeatedly on the upper two layers and the etch stop layer under the conditions shown in Tables 6 and 7, no deposition of residues occurred on the plasma surrounding parts and the etch rate did not change with time.

Although the invention has been described in its preferred form, it is understood that the embodiments are merely illustrative for the laminate structure, etching condition, etching equipment, etc. and they can be variously modified without departing from the scope of the invention.

1. A method for plasma etching an insulating layer by using a plasma etching equipment and a fluorocarbon etching gas, said method comprising
controlling the sheath potential that appears on the outermost surface of the plasma surrounding parts of the plasma etching equipment in response to the value of F₀/C₀, where C₀ and F₀ each denote the total amount of carbon atoms and fluorine atoms constituting the fluorocarbon etching gas, so as to avoid deposition of residues on said plasma surrounding parts.

2. The plasma etching method as defined in claim 1, wherein the etching gas contains oxygen gas in such an amount as to meet the condition that C₀>O₀, where O₀ denotes the total amount of oxygen atoms in the etching gas.

3. The plasma etching method as defined in claim 1, wherein the sheath potential that appears on the outermost surface of the plasma surrounding parts of the plasma etching equipment is kept higher than the potential at which no deposition of residues occurs on the plasma surrounding parts and is kept lower than the potential at which the material constituting the plasma surrounding parts substantially undergoes etching.

4. The plasma etching method as defined in claim 1, wherein the material constituting the insulating layer contains silicon atoms.

5. A method for plasma etching each layer of an object of M-layered structure (M≧2) having at least one insulating layer by using a plasma etching equipment and a fluorocarbon etching gas, said method comprising
controlling the sheath potential that appears on the outermost surface of the plasma surrounding parts of the plasma etching equipment when the mth layer (m=1, 2, . . . M) undergoes plasma etching, in response to the value of Fₘ₋₀/Cₘ₋₀, where Cₘ₋₀ and Fₘ₋₀ each denote the total amount of carbon atoms and fluorine atoms constituting the fluorocarbon etching gas used for plasma etching of the mth layer, so as to avoid deposition of residues on said plasma surrounding parts.

6. The plasma etching method as defined in claim 5, wherein the etching gas used for plasma-etching at least the insulating layer contains oxygen gas in such an amount as to meet the condition that C₀>O₀, where O₀ denotes the total amount of oxygen atoms in the etching gas.

7. The plasma etching method as defined in claim 5, wherein the sheath potential that appears on the outermost surface of the plasma surrounding parts of the plasma etching equipment is kept higher than the potential at which no deposition of residues occurs on the plasma surrounding parts and is kept lower than the potential at which the material constituting the plasma surrounding parts substantially undergoes etching.

8. The plasma etching method as defined in claim 5, wherein the material constituting the insulating layer contains silicon atoms.
